(19) United States
(12) Patent Application Publication
(10) Pub. No.: US 2025/0218969 A1
(43) Pub. Date: Jul. 3, 2025

(54) SEMICONDUCTOR PACKAGE

(71) Applicant: Samsung Electronics Co., Ltd., Suwon-si (KR)

(72) Inventors: Hongwon KIM, Suwon-si (KR); Eunseok CHO, Suwon-si (KR); Seungsoo HA, Suwon-si (KR)

(73) Assignee: Samsung Electronics Co., Ltd., Suwon-si (KR)

(21) Appl. No.: 18/986,077

(22) Filed: Dec. 18, 2024

(30) Foreign Application Priority Data
Jan. 3, 2024 (KR) 10-2024-0001061

(51) Int. Cl. H01L 23/538; H01L 21/48; H01L 23/00; H01L 23/31; H01L 23/373; H01L 25/16

(52) U.S. Cl. CPC H01L 23/5386; H01L 21/4857; H01L 21/486; H01L 23/3128; H01L 23/3736; H01L 23/3737; H01L 23/3738; H01L 23/5385; H01L 25/165; H01L 24/08; H01L 24/16; H01L 24/32; H01L 24/73; H01L 2224/08235; H01L 2224/16227; H01L 2224/16238; H01L 2224/32225; H01L 2224/73204; H01L 2924/35121

(57) ABSTRACT

A semiconductor package may include a lower redistribution structure including redistribution patterns, a first semiconductor device on the lower redistribution structure, a core layer laterally apart from the first semiconductor device, the core layer on the lower redistribution structure and including a core insulating layer and core wires, an encapsulation material on the lower redistribution structure and at least partially covering side and upper surfaces of the core layer and of the first semiconductor device, a second semiconductor device on the encapsulation material, and a heat dissipation structure.

### CROSS-REFERENCE TO RELATED APPLICATION

This application is based on and claims priority under 35 U.S.C. § 119 to Korean Patent Application No. 10-2024-0001061, filed on Jan. 3, 2024, in the Korean Intellectual Property Office, the disclosure of which is incorporated by reference herein in its entirety.

### BACKGROUND

Inventive concepts relate to a semiconductor package, for example to a fan out semiconductor package.

According to the rapid development of the electronics industry and users' demands, electronic devices are becoming smaller, multi-functional, and higher capacity, and accordingly, highly-integrated semiconductor chips are desired or necessary. Accordingly, semiconductor packages having connection terminals with secured connecting reliability have been developed for highly-integrated semiconductor chips having an increased number of connection terminals for input/output. For example, fan out semiconductor packages having an increased interval between connection terminals have been developed in order to reduce or prevent interference between the connection terminals.

### SUMMARY

Inventive concepts relate to improving, for example, productivity, economic efficiency, thermal characteristics, and reliability of a semiconductor package.

It will be appreciated by one of ordinary skill in the art that that the objectives and effects that may be achieved with inventive concepts are not limited to what has been particularly described above and other objectives of inventive concepts will be more clearly understood from the following detailed description.

According to some aspects of inventive concepts, a semiconductor package may include a lower redistribution structure including redistribution patterns, a first semiconductor device on the lower redistribution structure, a core layer on the lower redistribution structure, the core layer laterally spaced apart from the first semiconductor device, and including a core insulating layer and core wires, an encapsulation material at least partially covering a side surface of the core layer, an upper surface of the core layer, a side surface of the first semiconductor device, and an upper surface of the first semiconductor device, a second semiconductor device on the encapsulation material, and a heat dissipation structure laterally apart from the second semiconductor device and disposed above the first semiconductor device, wherein the core wires include core patterns and core vias, upper vias at least partially extend through the encapsulation material and upper pads are on uppermost of the core patterns, the uppermost core patterns on an uppermost surface of the core layer, the upper pads being integrally connected to the upper vias, the upper vias connect the uppermost core patterns to the upper pads, the upper pads are on the upper surface of the encapsulation material, and upper surfaces and side surfaces of the upper pads are at least partially covered by a cover conductive layer and the cover conductive layer contacts the upper surface of the encapsulation material.

According to some aspects of inventive concepts, a semiconductor package may include a lower redistribution structure including redistribution patterns; a first semiconductor device on the lower redistribution structure; a core layer laterally apart from the first semiconductor device, on the lower redistribution structure, and including a plurality of core insulating layers and core wires; an encapsulation material on the lower redistribution structure and between the core layer and the first semiconductor device, the encapsulation material at least partially covering a side surface of the core layer, an upper surface of the core layer, a side surface of the first semiconductor device, and an upper surface of the first semiconductor device; a second semiconductor device on the encapsulation material; and a heat dissipation structure laterally apart from the second semiconductor device and above the first semiconductor device, wherein the core wires include core patterns and core vias, upper vias at least partially extend through the encapsulation material and upper pads are on uppermost of the core patterns, the uppermost core patterns being on an uppermost surface of the core layer, the upper pads being connected to the upper vias, the upper vias connect the uppermost core patterns to the upper pads, the upper pads are on the upper surface of the encapsulation material, upper surfaces and side surfaces of the upper pads are at least partially covered by a cover conductive layer, the cover conductive layer contacting the upper surface of the encapsulation material, a planar shape of the first semiconductor device does not overlap a planar shape of the second semiconductor device, and a planar shape of the heat dissipation structure includes the planar shape of the first semiconductor device, the first semiconductor device includes at least one of a central processor device chip, a graphic processing device chip, and an application processor chip, and the second semiconductor device includes at least one memory chip.

According to some aspects of inventive concepts, a semiconductor package may include a lower redistribution structure including redistribution patterns; a first semiconductor device on the lower redistribution structure; a core layer laterally apart from the first semiconductor device, on the lower redistribution structure, and including core wires and a core insulating layer, the core wires including core patterns and core vias; an encapsulation material on the lower redistribution structure and at least partially covering a side surface of the core layer, an upper surface of the core layer, a side surface of the first semiconductor device, and an upper surface of the first semiconductor device; a second semiconductor device on the encapsulation material; a heat dissipation structure laterally apart from the second semiconductor device and above the first semiconductor device; an upper underfill layer between the second semiconductor device and the encapsulation material; and a thermal transfer film on the lower surface of the heat dissipation structure, wherein upper vias at least partially extending through the encapsulation material and upper pads integrally extending from the upper vias are on uppermost of the core patterns, the uppermost core patterns on an uppermost surface of the core layer, the upper vias connect the uppermost core patterns to the upper pads, the upper pads are on the upper surface of the encapsulation material, upper surfaces and side surfaces of the upper pads are at least partially covered by a cover conductive layer, the cover conductive layer contacting the upper surface of the encapsulation material, the upper pads are located vertically above the uppermost core pattern, the upper vias are vertically between the uppermost core patterns and the upper pads, and the uppermost core patterns, the upper vias, and the upper pads are aligned in a vertical direction, seed layers extend between the encapsulation material and the upper pads, between the upper vias and the encapsulation material, and between the upper vias and the uppermost core patterns, the upper underfill layer contacts with at least a part of the cover conductive layer and does not contact the upper pad, the upper surface of the second semiconductor device and an upper surface of the heat dissipation structure are coplanar with each other, the redistribution patterns include redistribution line patterns and redistribution vias, individual redistribution vias have a horizontal width that increases when moving vertically away from the first semiconductor device and individual core vias have a horizontal width that increases when moving vertically away from the lower redistribution structure, the first semiconductor device includes at least one of a central processor device chip, a graphic processing device chip, and an application processor chip, and the second semiconductor device includes at least one memory chip, a lower surface of the first semiconductor device contacts the upper surface of the lower redistribution structure, a planar shape of the first semiconductor device does not overlap a planar shape of the second semiconductor device, a planar shape of the heat dissipation structure includes the planar shape of the first semiconductor device, and a planar shape of the thermal transfer film is same as or greater than a planar shape of the heat dissipation structure, the heat dissipation structure includes at least one of silicon or a metal including at least one of aluminum (Al), copper (Cu), titanium (Ti), nickel (Ni), iron (Fe), cobalt (Co), palladium (Pd), platinum (Pt), aurum (Au), lead (Pb), Argentum (Ag), Carbon (C), tin (Sn), tungsten (W), and chromium (Cr), or any alloy thereof, the cover conductive layer includes at least one of Au or Ni, and the encapsulation material includes an epoxy mold compound (EMC), the thermal transfer film includes a thermal interface material (TIM), the TIM including at least one of mineral oil, grease, gap filler putty, phase change gel, phase change material pads, or particle filled epoxy, and a thickness of the encapsulation material in the vertical direction is 200 μm to 500 μm, and a distance in the vertical direction between an upper surface of an uppermost portion of the core insulating layer and the upper surface of the encapsulation material is 50 μm to 90 μm.

### BRIEF DESCRIPTION OF THE DRAWINGS

Example embodiments will be more clearly understood from the following detailed description taken in conjunction with the accompanying drawings in which:

FIG. 1 is a cross-sectional view of a semiconductor package according to some example embodiments;

FIG. 2 is a cross-sectional view showing an enlarged view of part A in FIG. 1;

FIG. 3 is a cross-sectional view of the semiconductor package taken along line I-I′ of FIG. 1;

FIG. 4 is a cross-sectional view of a semiconductor package according to some example embodiments; and

FIGS. 5A to 5H are cross-sectional views illustrating methods of manufacturing a semiconductor package according to some example embodiments.

FIG. 6 is a schematic view illustrating a semiconductor package according to some example embodiments.

### DETAILED DESCRIPTION OF THE EMBODIMENTS

Hereinafter, one or more example embodiments of inventive concepts will be described in detail with reference to accompanying drawings.

Embodiments of inventive concepts are non-limiting, and thus the scope of various aspects of inventive concepts should not necessarily be limited by any particular characteristics of the provided example embodiments. Rather, these example embodiments are provided so that this description will be thorough and complete, and will fully convey inventive concepts to one of ordinary skill in the art. In addition, the thickness or size of each layer in the drawings may be understood as exaggerated for the convenience and clarity of each component.

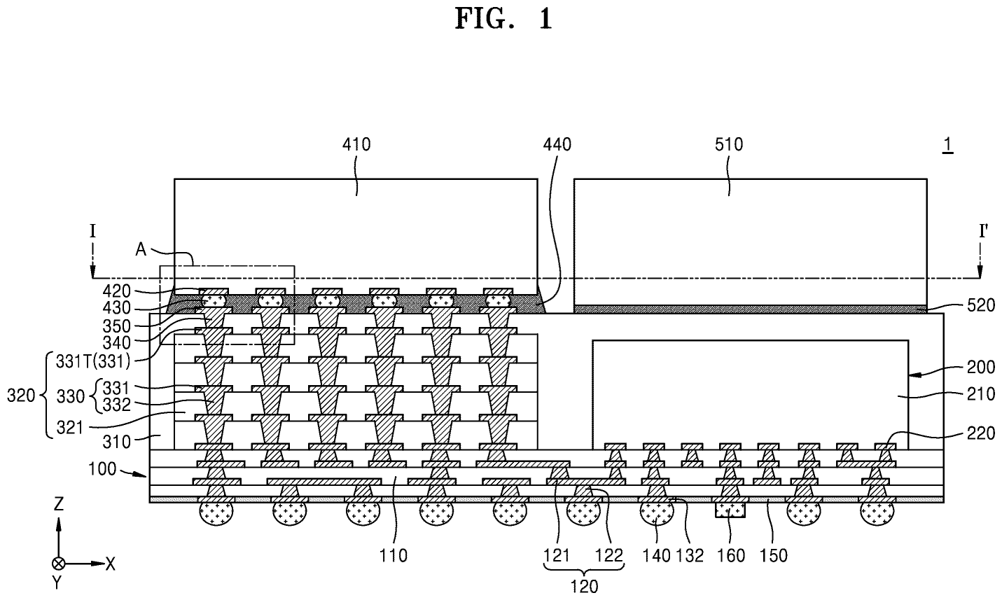

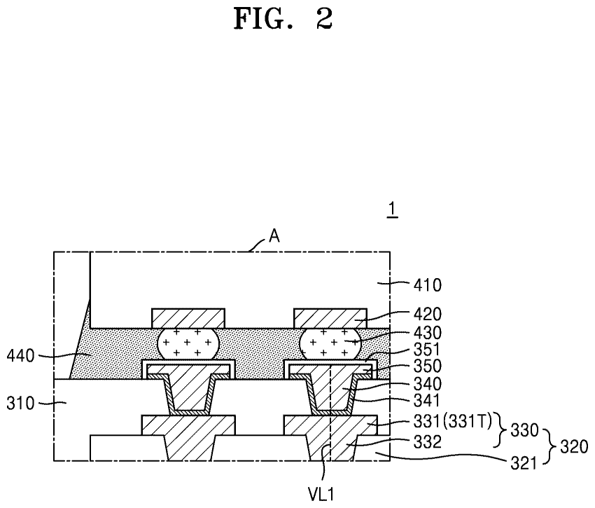

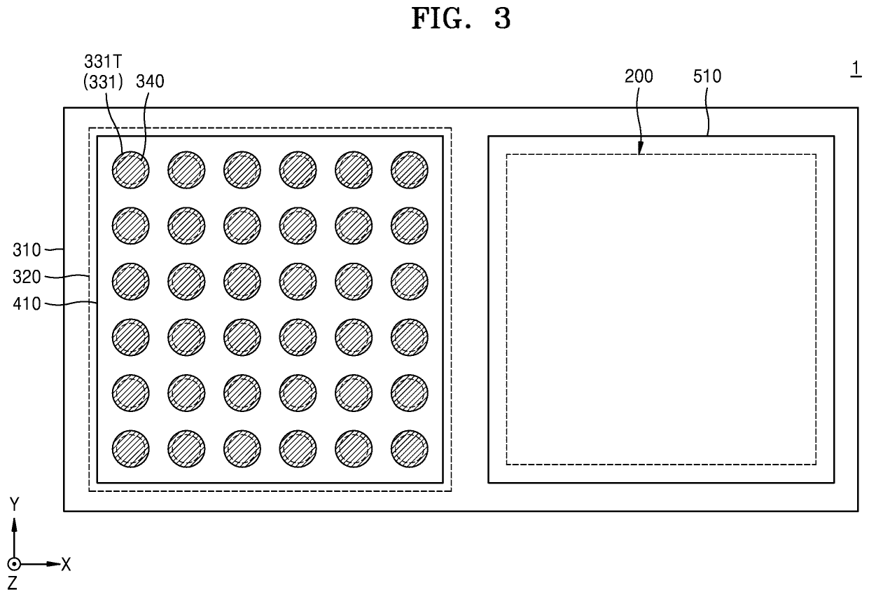

FIG. 1 is a cross-sectional view of a semiconductor package 1 according to some example embodiments. FIG. 2 is a cross-sectional view showing an enlarged view of part A in FIG. 1. FIG. 3 is a plan view of the semiconductor package 1 taken along line I-I′ of FIG. 1.

In the specification, a first direction may denote an X direction and a second direction may denote a Y direction, wherein the first direction and the second direction may be perpendicular to each other. A third direction denotes a Z direction and may be perpendicular to each of the first direction and the second direction. A horizontal plane or a plane denotes an XY plane. An upper surface of a certain object denotes a surface located in the positive third direction based on the certain object, and a lower surface of the certain object denotes a surface located in a negative third direction based on the certain object.

Referring to FIGS. 1 to 3, the semiconductor package 1 may include a lower redistribution structure 100, an inner semiconductor device 200, a core layer 320, an encapsulation material 310, an outer semiconductor device 410, and a heat dissipation structure 510. The semiconductor package 1 may be understood as, for example, a fan out semiconductor package, in which a horizontal width and a horizontal area of the lower redistribution structure 100 are greater than a horizontal width and horizontal area, respectively, formed by the inner semiconductor package 200. In some example embodiments, the semiconductor package 1 may be understood as, for example, a fan out panel level package (FOPLP). In the specification, the inner semiconductor device 200 may be referred to as a first semiconductor device, and the outer semiconductor device 410 may be referred to as a second semiconductor device.

In some example embodiments, the lower redistribution structure 100 may be formed through, for example, a redistribution process. The lower redistribution structure 100 may include, for example, a redistribution insulating layer 110 and a plurality of redistribution patterns 120. The redistribution insulating layer 110 may surround (for example, cover or at least partially cover) any or each the plurality of redistribution patterns 120. In some example embodiments, the lower redistribution structure 100 may include (for example, be in the form of) a plurality of redistribution insulating layers 110 that are stacked. The redistribution insulating layer 110 may include or be formed of, for example, a photo imagable dielectric (PID) and/or a photosensitive polyimide (PSPI), but example embodiments are not limited thereto.

A passivation layer 150 may be provided on the lower surface of the lower redistribution structure 100. The passivation layer 150 may protect the lower redistribution structure 100 and may include, for example, polymer. and the passivation layer 150 may cover or at least partially cover side surfaces and/or lower surfaces of any or each of a plurality of outer connection pads 132.

The plurality of redistribution patterns 120 may include a plurality of redistribution line patterns 121 and a plurality of redistribution via patterns 122. The plurality of redistribution patterns 120 may include, for example, one or more metals, such as, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or any alloy thereof, but example embodiments are not limited thereto.

Ones of the plurality of redistribution line patterns 121 may be disposed on at least one of the upper surface (for example, uppermost surface) and the lower surface of the redistribution insulating layer 110. For example, when the lower redistribution structure 100 includes the plurality of redistribution insulating layers 110 that are stacked, ones of the plurality of redistribution line patterns 121 may be disposed on an upper surface of the uppermost redistribution insulating layer 110, a lower surface of the lowermost redistribution insulating layer 110, and between neighboring redistribution insulating layers 110.

The plurality of redistribution via patterns 122 may be connected to some of the plurality of redistribution line patterns 121 through the redistribution insulating layers 110. In some example embodiments, one or more distribution via patterns 122 of the plurality of redistribution via patterns 122 may have a tapered or substantially tapered shape of which a horizontal width reduces toward (for example, when moving upwards in a vertical direction toward) the encapsulation material 310. Similarly, one or more distribution via patterns 122 of the plurality of redistribution via patterns 122 may have a tapered or substantially tapered shape of which a horizontal width increases away (for example, when moving downwards in a vertical direction away from) from the inner semiconductor device 200.

In some example embodiments, some of the plurality of redistribution line patterns 121 may be formed along with some of the plurality of redistribution via patterns 122 to be integrated. For example, the redistribution line pattern 121 and the redistribution via pattern 122 coming into contact with the lower surface of the redistribution line pattern 121 may be integrally formed along with each other.

Some of the plurality of redistribution line patterns 121, for example, those which may arranged on the lower (for example, lowermost) surface of the lower redistribution structure 100 to be adjacent to each other, may be referred to as a plurality of outer connection pads 132. In other words, the plurality of outer connection pads 132 may be or include some of the plurality of redistribution line patterns 121, for example those which may be arranged on the lower (for example, lowermost) surface of the lower redistribution structure 100 to be adjacent to each other.

A plurality of outer connection terminals 140 may be attached to the plurality of outer connection pads 132. The plurality of outer connection terminals 140 may, for example, connect the semiconductor package 1 to the outside (for example, to an external device). In some example embodiments, the plurality of outer connection terminals 140 may individually include, for example, a solder bump and/or solder ball, but example embodiments are not limited thereto.

At least one passive element 160 may be attached to at least some of the plurality of outer connection pads 132. Although not shown in FIG. 1, the passive element 160 be provided in the form of a plurality of passive elements 160. Any of all of the passive elements 160 may be electrically connected to the inner semiconductor device 200 via the lower redistribution structure 100. The passive elements 160 may individually include at least one of a capacitor, a resistor, an inductor, etc.

At least one inner semiconductor device 200 may be mounted on the lower redistribution structure 100. For example, there may be a single inner semiconductor device 200 or a plurality of inner semiconductor devices 200. The inner semiconductor device 200 may include, for example, a semiconductor substrate 210, and/or first connection pads 220 arranged on a lower surface of the semiconductor substrate 210. For example, the inner semiconductor device 200 may have a thickness of about 150 μm or greater in the vertical direction. In the specification, the lower surface of the inner semiconductor device 200 may denote a surface facing the lower redistribution structure 100, and the upper surface of the inner semiconductor device 200 may denote a surface opposite to (for example, in a vertical direction) the inner semiconductor device 200. In some example embodiments, the inner semiconductor device 200 may have a face down arrangement, in which an active surface (for example, a surface on which elements may be arranged) of the inner semiconductor device 200 faces the lower redistribution structure 100 and may be mounted on the upper surface of the lower redistribution structure 100. The first connection pads 220 may individually include, for example, pads and/or studs, but example embodiments are not limited thereto. Some of the plurality of redistribution via patterns 122 provided on the uppermost surface of the lower redistribution structure 100 (for example, those in an uppermost layer or layer vertically closest to an inner semiconductor device 200). May be electrically connected (for example, directly electrically connected) to the first connection pads 220.

The semiconductor substrate 210 may include, for example, at least one semiconductor material, such as, for example, silicon (Si) and/or germanium (Ge), but example embodiments are not limited thereto. Alternatively or additionally, the semiconductor substrate 210 may include a compound semiconductor material such as, for example, silicon carbide (SiC), gallium arsenide (GaAs), indium arsenide (InAs), and indium phosphide (InP). The semiconductor substrate 210 may include, for example, a well doped with impurities, for example a conductive region. The semiconductor substrate 210 may include, for example, one or more of various isolation structures, e.g., one or more of a shallow trench isolation (STI).

Semiconductor elements such as, for example, various kinds of individual devices may be formed on the active surface of the semiconductor substrate 210. The plurality of individual devices may be electrically connected, on an individual basis, to the conductive region of the semiconductor substrate 210. The semiconductor element may further include a conductive wire and/or conductive plug electrically connecting the plurality of individual devices to the conductive region of the semiconductor substrate 210. Also, the plurality of individual devices may be electrically isolated from adjacent other individual devices by insulating layers, but example embodiments are not limited thereto.

In some example embodiments, the inner semiconductor device 200 may include a logic element. For example, the inner semiconductor device 200 may include a central processing device chip, a graphic processing device chip, and/or an application processor chip. In some example embodiments, when the semiconductor package 1 includes a plurality of inner semiconductor devices 200, one of the plurality of inner semiconductor devices 200 may be or include, for example, a central processing apparatus chip, a graphic processing apparatus chip, and/or an application processor chip, and one another may be or include, for example, a memory semiconductor chip including a memory device.

For example, the memory device may include a non-volatile memory such as a flash memory, a phase-change random access memory (PRAM), a magnetoresistive random-access memory (MRAM), a ferroelectric random-access memory (FeRAM), and/or a resistive random-access memory (RRAM). In some example embodiments, the memory device may include a volatile memory device such as a dynamic RAM (DRAM) or a static RAM (SRAM).

Although not fully illustrated in the drawings, the inner semiconductor device 200 may include a plurality of semiconductor chips that are stacked in the vertical direction. The plurality of semiconductor chips may be a stacked (plurality of) semiconductor chips provided with through-silicon vias (TSV).

The core layer 320 may be arranged on the lower redistribution structure 100. The core layer 320 may be laterally spaced apart from the inner semiconductor device 200. The core layer 320 may be spaced apart from the inner semiconductor device 200 in one lateral (for example, horizontal) direction. As shown in FIG. 1, the core layer 320 may be arranged only in a negative first direction from the inner semiconductor device 200 and may not be arranged in the positive first direction, the positive second direction, and the negative second direction from the inner semiconductor device 200. FIG. 3 shows the arrangement of the core layer 320. That is, the core layer 320 may not be located around the inner semiconductor device 200, but may be located on one side thereof.

In the semiconductor package 1 according to some example embodiments, an additional redistribution structure may not be provided on the upper surface of the encapsulation material 310 and an external semiconductor device 410 and the lower redistribution structure 100 are electrically connected to each other via the core layer 320, and thus, the core layer 320 may be located below the external semiconductor device 410.

The core layer 320 may include core insulating layers 321 and core wires 330. The core wire 330 may include core patterns 331 and core vias 332. The core layer 320 may be spaced laterally from the inner semiconductor device 200 and may be disposed on the lower redistribution structure 100. A part in an upper surface and a side surface of the core layer 320 may be surrounded (for example, covered or at least partially covered) by the encapsulation material 310. The core patterns 331 and the core vias 332 may be arranged to electrically connect the upper and lower surfaces of the core layer 320 to each other. The core patterns 331 may be arranged in the core insulating layer 321, but example embodiments are not limited thereto. From among the core patterns 331, the core patterns 331 exposed through the lower surface of the core layer 320 may be embedded in the core insulating layer 321, and this may be a structure obtained according to manufacturing processes. The core insulating layer 321 may be referred to as a base substrate. The core patterns 331 provided in the lowermost core insulating layer 321 may be arranged to correspond to some of the plurality of redistribution via patterns 122 provided on the uppermost surface of the lower redistribution structure 100 and may be electrically connected to some of the plurality of redistribution via patterns 122 provided on the uppermost surface of the lower redistribution structure 100.

The encapsulation material 310 may surround (for example, cover or at least partially cover) the inner semiconductor device 200 and the core layer 320 on the upper surface of the lower redistribution structure 100. The encapsulation material 310 may come into contact with, the side surfaces of the inner semiconductor device 200, the upper surface of the inner semiconductor device 200, the side surfaces of the core layer 320, and a part of the upper surface of the core layer 320. The upper surface of the encapsulation material 310 may be a flat or substantially flat surface. On the upper surface of the encapsulation material 310, the outer semiconductor device 410 and the heat dissipation structure 510 may be disposed. A vertical level of the upper surface of the encapsulation material 310 from (for example, a vertical distance between) the lower redistribution structure 100 may be greater than that of the upper surface of the inner semiconductor device 200 from the lower redistribution structure 100. Accordingly, the encapsulation material 310 may be disposed on the upper surface of the inner semiconductor device 200 (for example, interposed between the upper surface of the inner semiconductor device 200 and heat dissipation structure 510).

In some example embodiments, the side surfaces of the lower redistribution structure 100 and the side surfaces of the encapsulation material 30 may be aligned perpendicularly to each other to be coplanar. The encapsulation material 310 may have a thickness of, for example, about 200 μm to about 400 μm, but example embodiments are not limited thereto. The encapsulation material 310 may be or include, for example, a molding member including, for example, epoxy mold compound (EMC), but example embodiments are not limited thereto. The encapsulation material 310 may further include a filler.

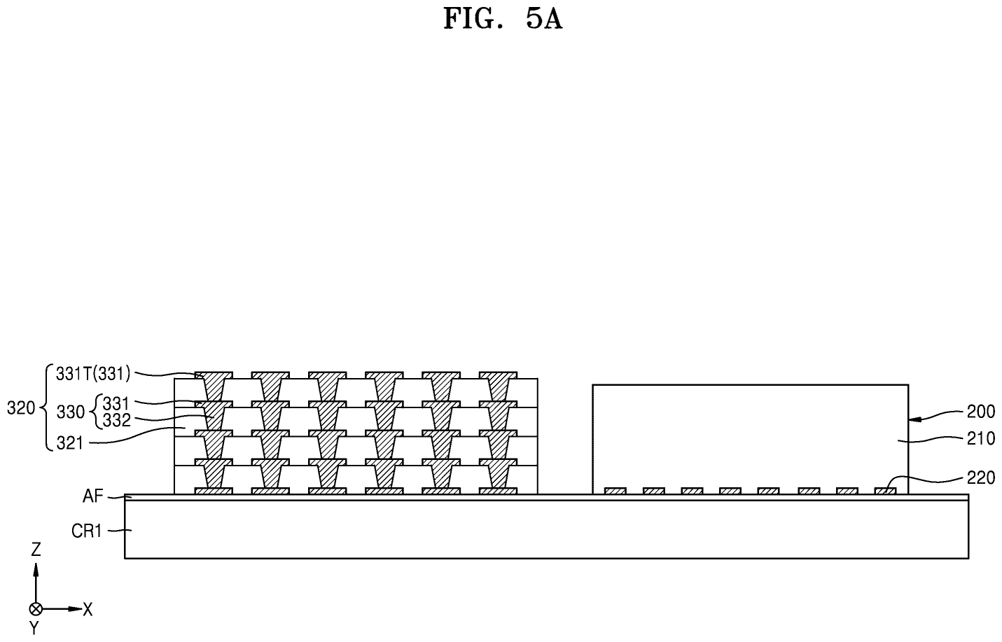

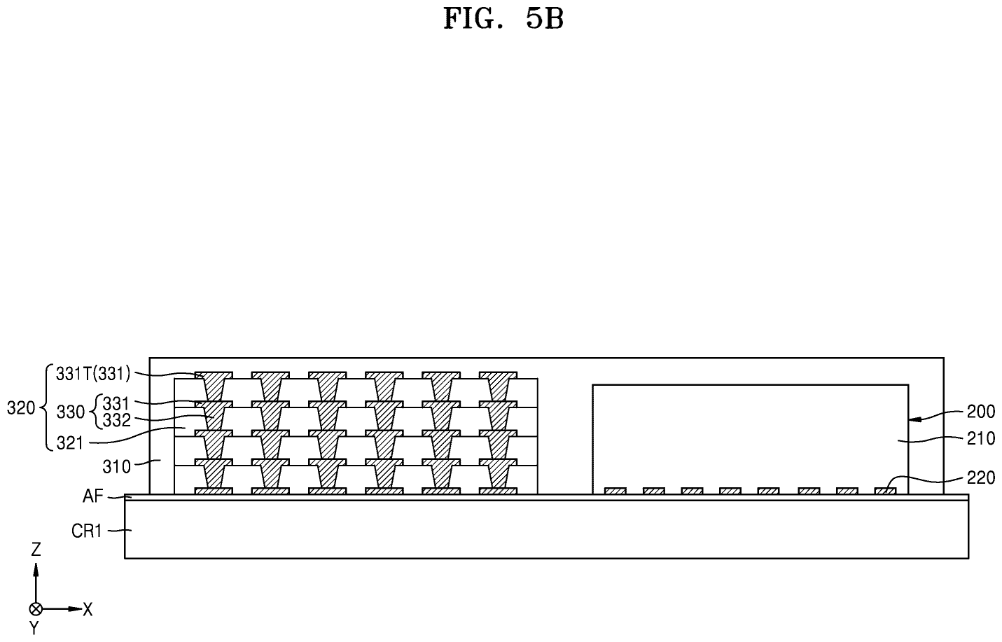

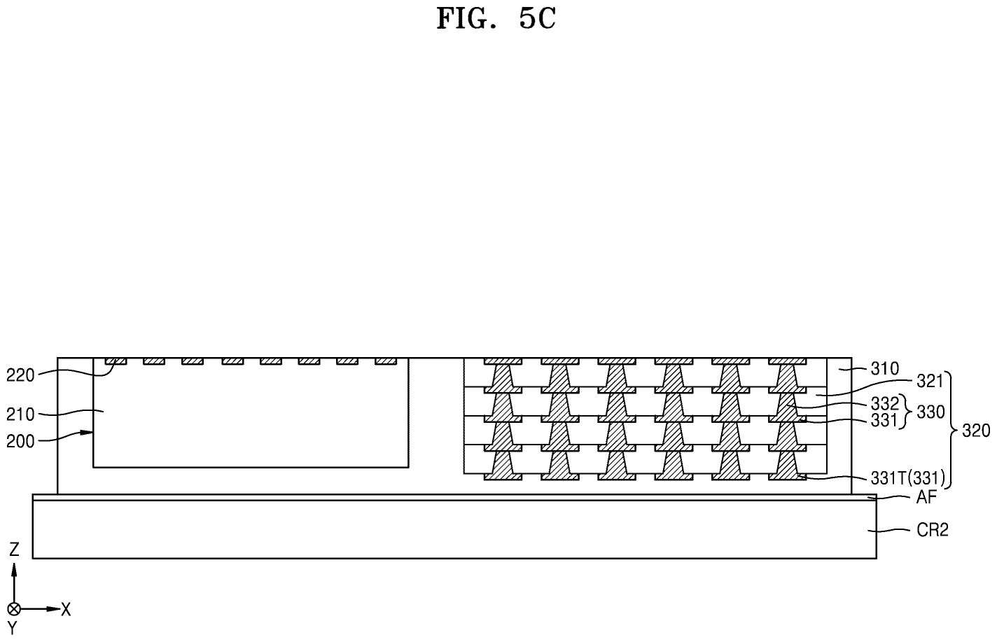

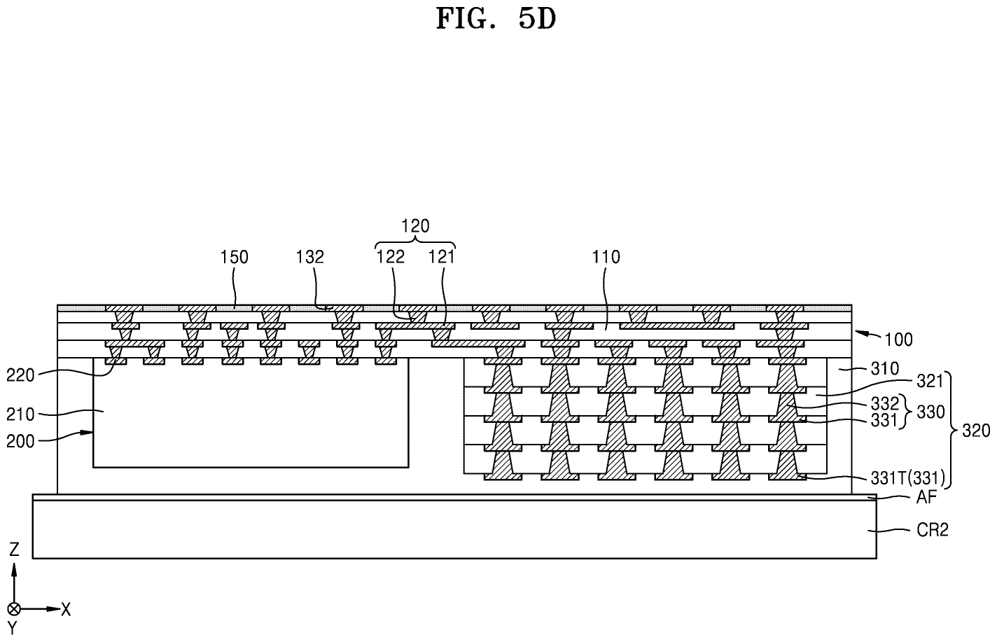

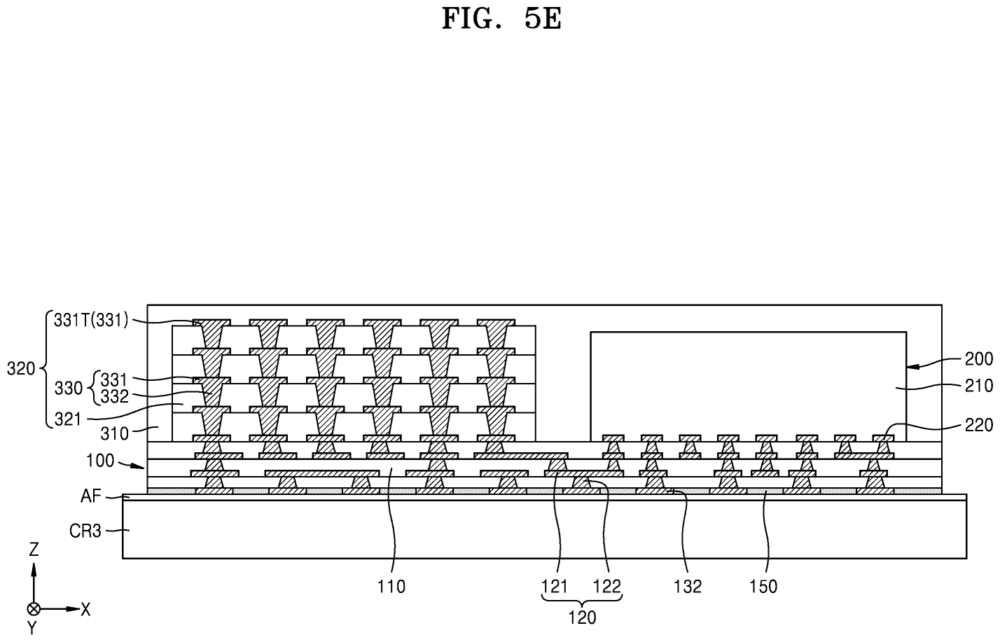

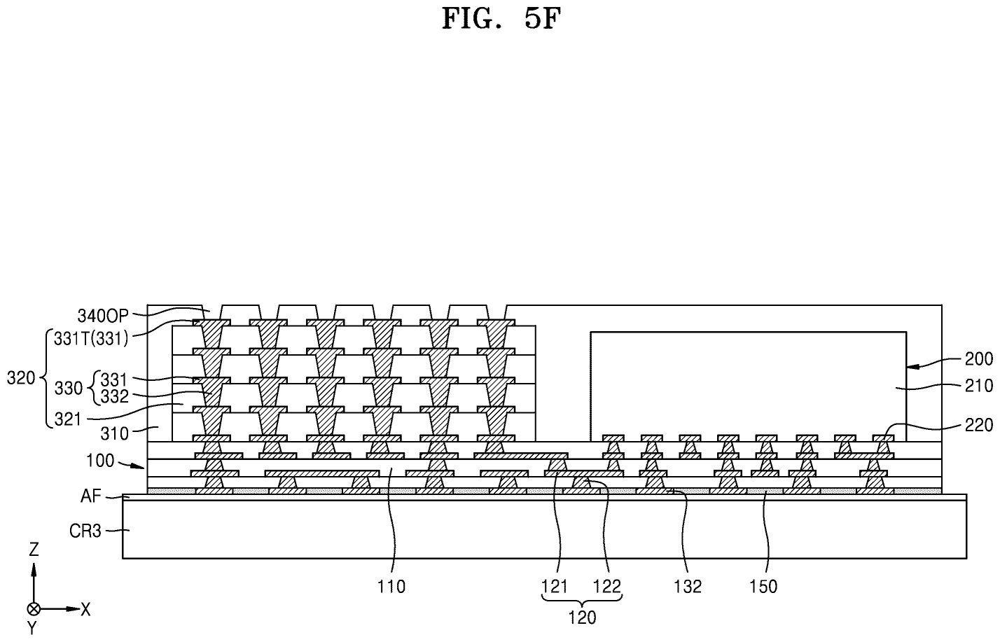

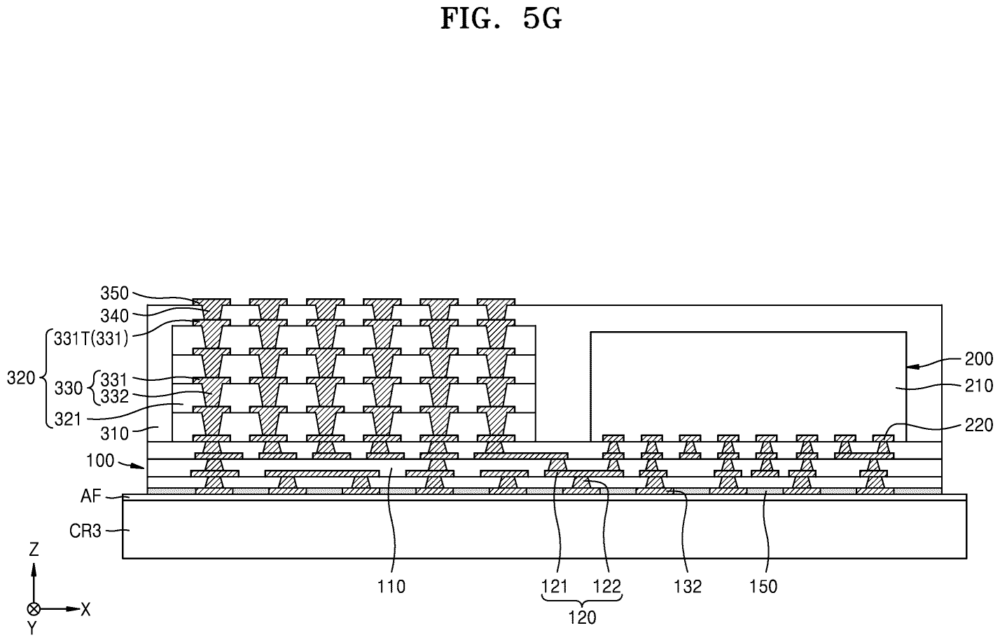

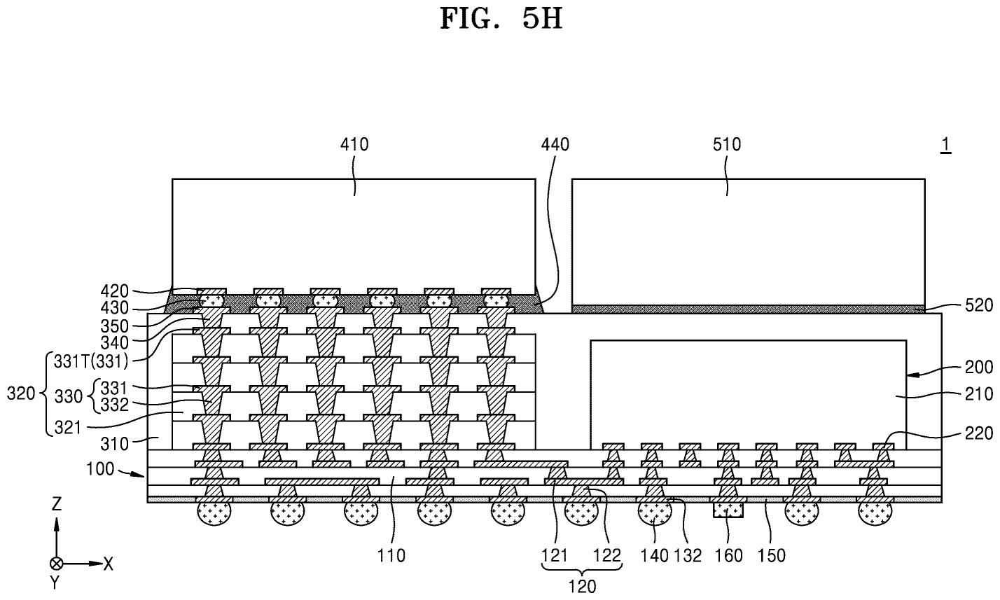

As shown in FIG. 2, the upper vias 340 and the upper pads 350 may be formed on seed layers 341. As described with reference to FIG. 5F below, first openings 340OP may be formed in (for example, defined by) the encapsulation material 310 and the seed layers 341 may be formed in the first openings 340OP. The seed layer 341 may be disposed on the upper surface of the encapsulation material 310, side walls forming (for example, defining or at least partially defining) the first opening 340OP, and a part of the upper surface of the upper pad 350 so as to be connected on the upper surface of the encapsulation material 310, the side walls of (for example, defining or at least partially defining) the first opening 340OP, and the part of the upper surface of the upper pad 350. The seed layer 341 may be formed through a sputtering process or an electroless plating process.

The upper vias 340 and the upper pads 350 may be integrally provided in the first openings 340OP, and the upper surfaces and side surfaces of the upper pads 350 may be surrounded by cover conductive layers 351. In some example embodiments, the cover conductive layer 351 may include at least one metal plating layer. The metal plating layer may include metal including aurum (Au). In some example embodiments, the cover conductive layer 351 may include a first metal plating layer and a second metal plating layer. The first metal plating layer may include, for example, Au, and the second plating layer may include, for example, Ni, but example embodiments are not limited thereto. The cover conductive layer 351 may come into contact with the upper surface of the encapsulation material 310, the upper surface of the upper pad 350, and the side surface of the upper pad 350. The upper surface of the cover conductive layer 1351 may at least partially come into contact with connection terminals 430. An outer underfill layer 440 may surround the cover conductive layers 351. The outer underfill layer 440 and the upper pads 350 may be spaced apart from each other by the cover conductive layers 351.

From among the core patterns 331, uppermost core patterns 331T located at the uppermost portion of the core layer 320 and the core vias 332 provided integrally with the uppermost core patterns 331T may be aligned in the vertical direction. A virtual line that is a reference of the alignment may be referred to as a first vertical line VL1. Also, the upper vias 340 and the upper pads 350 may be aligned in the vertical direction. Aligning (for example, being aligned) in the vertical direction may denote that center axes (for example, in a horizontal direction) of a plurality of objects are the same or substantially the same as one another.

The uppermost core patterns 331T, the core vias 332, the upper vias 340, and the upper pads 350 may be aligned based on the first vertical line VL1. The semiconductor package 1 according to some example embodiments does not include an additional redistribution structure on the upper surface of the encapsulation material 310, which is a surface facing the lower redistribution structure 100, and thus, the core layer 320 and the outer semiconductor device 410 may be connected to each other via the upper vias 340 and the upper pads 350. Accordingly, the upper vias 340, the upper pads 350, and the uppermost core patterns 331T may be aligned in the vertical direction.

From among the plurality of core insulating layers 321 included in the core layer 320, a distance in the vertical direction between the upper surface of the core insulating layer 321 located at the uppermost portion and the upper surface of the encapsulation material 310 may be from about 50 μm to about 90 μm. When the upper surface of the core insulating layer 321 at the uppermost portion and the upper surface of the encapsulation material 310 are excessively or substantially excessively close to each other in the vertical direction, the electrical characteristics thereof may degrade, and when the upper surface of the core insulating layer 321 at the uppermost portion and the upper surface of the encapsulation material 310 are excessively or substantially excessively far from each other in the vertical direction, manufacturing processes may not be efficiently performed.

In some example embodiments, the outer underfill layer 440 surrounding the connection terminals 430 may be interposed between the outer semiconductor device 410 and the encapsulation material 310. In some example embodiments, the outer underfill layer 440 fills the space between the inner semiconductor device 200 and the encapsulation material 310, and may at least partially cover the lower side of the side surface of the outer semiconductor device 410 or may cover the lower surface of the outer semiconductor device 410. The outer underfill layer 440 may be formed by, for example, a capillary underfill process and may include, for example, an epoxy resin, but example embodiments are not limited thereto.

The outer semiconductor device 410 may include the second connection pads 420 arranged in or on the lower surface of the outer semiconductor device 410. The second connection pads 420 may be electrically connected to the upper pads 350 via the connection terminals 430. The semiconductor device 410 may denote a single semiconductor chip or may collectively refer to a stack of a plurality of semiconductor chips. The outer semiconductor device 410 may include a logic element. For example, the outer semiconductor device 410 may include a central processing device chip, a graphic processing device chip, or an application processor chip. In some example embodiments, when the outer semiconductor device 410 includes a plurality of semiconductor chips, one of the plurality of semiconductor chips included in the outer semiconductor device 410 may be a central processing device chip, a graphic processing device chip, or an application processor chip, and at least one another may be a memory semiconductor chip including a memory device.

For example, the memory device may include a non-volatile memory such as a flash memory, a PRAM, a MRAM, a FeRAM, or a RRAM. In some example embodiments, the memory device may include a volatile memory device such as a DRAM or a SRAM.

Although not shown in the drawings, the outer semiconductor device 410 may include a plurality of semiconductor chips that are stacked in the vertical direction. The plurality of semiconductor chips may be a stacked plurality of semiconductor chips provided with TSV. For example, the outer semiconductor device 410 may be or include a high bandwidth memory (HBM), but example embodiments are not limited thereto.

The heat dissipation structure 510 is laterally spaced apart from the outer semiconductor device 410 and may be arranged on the encapsulation material 310. A thermal transfer film 520 may be interposed between the heat dissipation structure 510 and the encapsulation material 310. A planar shape of the thermal transfer film 520 may be, for example, the same as, substantially the same as, or greater than a horizontal cross-section of the heat dissipation structure 510. As shown in FIG. 3, the shape of the heat dissipation structure 510 in a planar view may be greater than the shape of the inner semiconductor device 200 in a planar view. For example, the shape of the heat dissipation structure 510 in the planar view may include (for example, encompass) the shape of the inner semiconductor device 200 in the planar view.

In other words, the shape of the heat dissipation structure 510 overlapping the lower redistribution structure 100 may include the shape of the inner semiconductor device 200 overlapping the lower redistribution structure 100.

The heat dissipation structure 510 may include, for example, silicon, or may include metal including at least one of Al, Cu, Ti, Ni, iron (Fe), Co, palladium (Pd), platinum (Pt), Au, lead (Pb), Argentum (Ag), Carbon (C), Sn, tungsten (W), and chromium (Cr) or any alloy thereof, but example embodiments are not limited thereto.

The thermal transfer film 520 may include a thermal interface material (TIM). The thermal transfer film 520 may have higher thermal conductivity as compared with a general adhesive material. The thermal transfer film 520 may attach the heat dissipation structure 510 to the upper surface of the encapsulation material 310, and at the same time, may receive the heat generated from the inner semiconductor device 200 and transferred to the encapsulation material 310. In general, the thermal transfer film 520 may have a structure in which fillers such as metal particles are dispersed in a polymer material. The TIM may include, for example, mineral oil, grease, gap filler putty, phase change gel, phase change material pads, and/or particle filled epoxy, but example embodiments are not limited thereto.

As shown in FIG. 3, the planar shape of the inner semiconductor device 200 and the planar shape of the outer semiconductor device 410 may not overlap with each other. This may be provided for effective heat dissipation from the inner semiconductor device 200. For example, in FIG. 3, the planar shape of the inner semiconductor device 200 is indicated by dashed lines at the right side, and the planar shape of the outer semiconductor device 410 is indicated by solid lines at the left side. In other words, an overlapping shape between the inner semiconductor device 200 and the lower redistribution structure 100 and an overlapping shape between the outer semiconductor device 410 and the lower redistribution structure 100 may not overlap with each other.

The heat generated from the inner semiconductor device 200 may be transferred to the vicinity (for example, nearby area and/or structures) via the encapsulation material 310 that is in contact with the upper surface of the inner semiconductor device 200. A general (for example, conventional) semiconductor package generally utilizes an upper redistribution structure for mounting an outer semiconductor device, when the semiconductor package includes the outer semiconductor device. In such a general semiconductor package, the heat generated from the inner semiconductor device 200 may not be sufficiently dissipated due to the upper redistribution structure that is disposed above the encapsulation material.

On the contrary, the semiconductor package 1 according to some example embodiments of inventive concepts excludes the upper redistribution structure that is generally provided on the upper surface of the encapsulation material 310. Unlike the electrical connection among the core layer, the upper redistribution structure, and the outer semiconductor device in the general semiconductor package, an electrical connection among the core layer 320, the upper vias 340, the upper pads 350, and the outer semiconductor device 410 may be provided. Accordingly, the semiconductor package 1 may not include the upper redistribution structure.

Because the semiconductor package 1 according to some example embodiments of inventive concepts may include the outer semiconductor device 410 mounted therein or thereon without using the upper redistribution structure, materials and processes required to form the upper redistribution structure may not be included or required in the processes of manufacturing the semiconductor package 1. Accordingly, the productivity and economic efficiency of the semiconductor package 1 according to some example embodiments may be improved.

Also, because the outer semiconductor device 410 may be disposed on the encapsulation material 310 without using the upper redistribution structure, heat generated from the inner semiconductor device 200 may be sufficiently dissipated. Moreover, because the heat dissipation structure 510 is provided on the upper surface of the encapsulation material 310 above the inner semiconductor device 200, the heat generated from the inner semiconductor device 200 may be transferred to the heat dissipation structure 510 and the heat dissipation from the inner semiconductor device 200 may be sufficiently performed. Therefore, the heat dissipating property of the semiconductor package 1 according to the some example embodiments may be improved.

Unlike some example embodiments of inventive concepts, when an upper pad that is directly connected to the upper semiconductor device via the connection terminals is arranged in the encapsulation material, the attachment force between the encapsulation material, for example a portion of the encapsulation material covering at least a part of the upper surface of the upper pad and the upper pad may not be not sufficient. Accordingly, separation between the upper pad and the encapsulation material may occur due to lack of attachment force.

When the separation between the upper pad and the encapsulation material occurs, during a post process of arranging the connection terminals (e.g., solder balls) on the upper pad, melted solder ball may infiltrate into the gap generated due to the separation, and thereby forming an unintentional layer. As such, cracks may occur in the encapsulation material close to the separation portion. Alternatively or additionally, when the separation between the upper pad and the encapsulation material occurs, cracks may occur in the encapsulation layer that is adjacent to the area or areas of separation, due to various reasons including the heat generation and stress from peripheral components, etc. For example, when the upper pad that is directly connected to the upper semiconductor device via the connection terminals is arranged in the encapsulation material and the encapsulation material covers at least a part of the upper surface of the upper pad, reliability issue or issues of the semiconductor package may occur.

In the semiconductor package 1 according to the some example embodiments, the upper pads 350 may not be surrounded (for example covered or at least partially covered) by the encapsulation material 310, but may be located on the upper surface of the encapsulation material 310 as shown in FIGS. 1 and 2. Through the above structure, the probability of generating an issue such as cracks in the encapsulation material 310 may be reduced or prevented. Therefore, the reliability of the semiconductor package 1 may be improved according to the some example embodiments.

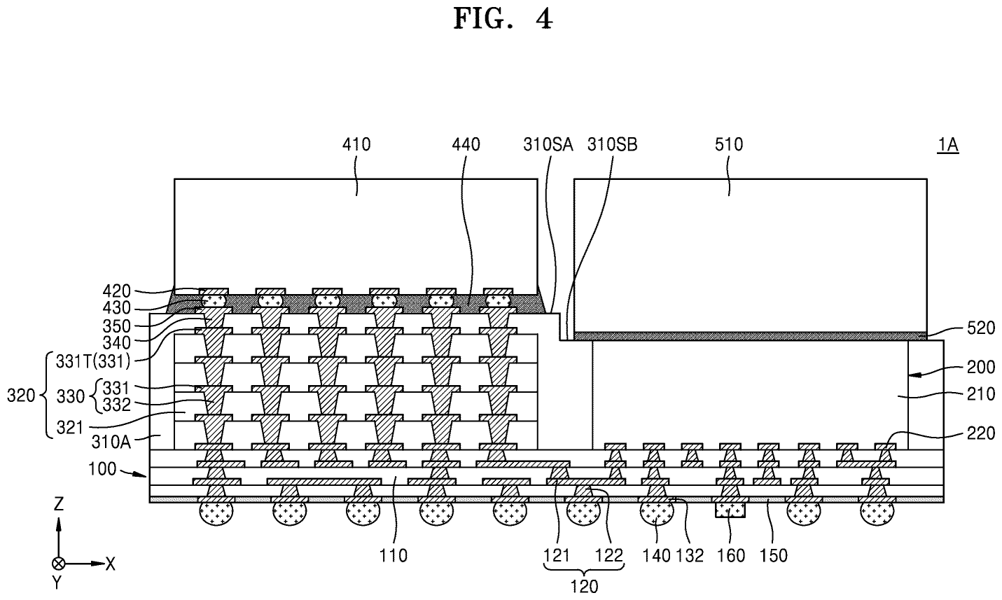

FIG. 4 is a cross-sectional view of a semiconductor package 1B according to some example embodiments.

Referring to FIG. 4, a first encapsulation material upper surface 310SA that is a part of the upper surface of an encapsulation material 310A and a second encapsulation material upper surface 310SB that is the remaining part of the upper surface of the encapsulation material 310A may not be coplanar. The first encapsulation material upper surface 310SA and the second encapsulation material upper surface 310SB may be at different vertical levels from each other. For example, a vertical level of the first encapsulation material upper surface 310SA from the upper surface of the lower redistribution structure 100 may be higher than a vertical level of the second encapsulation material upper surface 310SB from the upper surface of the lower redistribution structure 100.

The vertical level of the second encapsulation material upper surface 310SB may be equal to that of the upper surface of the inner semiconductor device 200. Therefore, the upper surface of the inner semiconductor device 200 may be exposed from (for example, at least partially uncovered by or not overlapping with) the encapsulation material 310A. Because the upper surface of the inner semiconductor device 200 and the heat dissipation structure 510 are directly connected to each other via the thermal transfer film 520, the heat generated from the inner semiconductor device 200 may be more sufficiently dissipated. For example, the heat dissipation characteristics of the semiconductor package 1A according to the some example embodiments may be improved.

The encapsulation material 310A in the semiconductor package 1A may be formed through an additional or alternative process in the processes of manufacturing the semiconductor package 1, in FIGS. 5A to 5H. For example, the upper portion of the encapsulation material 310 may be partially removed before placing the heat dissipation structure 510 on the encapsulation material 310A in FIG. 5F, and the encapsulation material 310A of the semiconductor package 1A of FIG. 4 may be obtained.

FIGS. 5A to 5H are cross-sectional views illustrating a method of manufacturing the semiconductor package 1 according to some example embodiments. Descriptions that are already provided above may be omitted.

Referring to FIGS. 5A and 5B, the core layer 320 and the inner semiconductor device 200 may be disposed on a first carrier CR1 and an attachment film AF. The core layer 320 and the inner semiconductor device 200 may be laterally spaced apart from each other.

The encapsulation material 310 may be formed to cover or at least partially cover the side surface and upper surface of the core layer 320 and the side surface and upper surfaces of the inner semiconductor device 200. The encapsulation material 310 may be, or include, for example, a molding member including an epoxy mold compound (EMC) and may further include a filler. After forming the encapsulation material 310, the upper portion of the encapsulation material 310 may be partially polished and removed by, for example, a chemical mechanical polishing (CMP) process, but example embodiments are not limited thereto.

Referring to FIGS. 5C and 5D, the first carrier CR1 and the attachment film AF are removed from the processing structure of FIG. 5B, and then, the processing structure of FIG. 5B is turned over and may be disposed on a second carrier CR2 and an attachment film AF. After that, the lower redistribution structure 100 may be formed through a redistribution process.

Referring to FIGS. 5E and 5F, the second carrier CR2 and the attachment film AF are removed from the processing structure of FIG. 5D, and after that, the processing structure of FIG. 5D is turned over and may be placed on a third carrier CR3 and the attachment film AF. After that, the first openings 340OP may be formed so that uppermost core patterns 331T that are located at the uppermost portion of the core layer 320, from among the core patterns 331, may be at least partially exposed to outside.

Referring to FIGS. 5G and 5H, the upper vias 340 and the upper pads 350 may be formed in the first openings 340OP provided in the processing structure of FIG. 5G. The upper vias 340 and the upper pads 350 may be formed along with each other to be integrated.

The outer semiconductor device 410 is mounted on the upper vias 340 and the connection terminals 430 are respectively interposed between the upper vias 340 and the second connection pads 420, and thus the connection terminals 430 may connect the upper vias 340 to the second connection pads 420.

Also, the heat dissipation structure 510 may be disposed on the upper surface of the encapsulation material 310. Also, a plurality of outer connection terminals 140 and at least one passive element 160 may be arranged respectively (for example, individually) on the plurality of outer connection pads 132 provided in the lower surface of the lower redistribution structure 100.

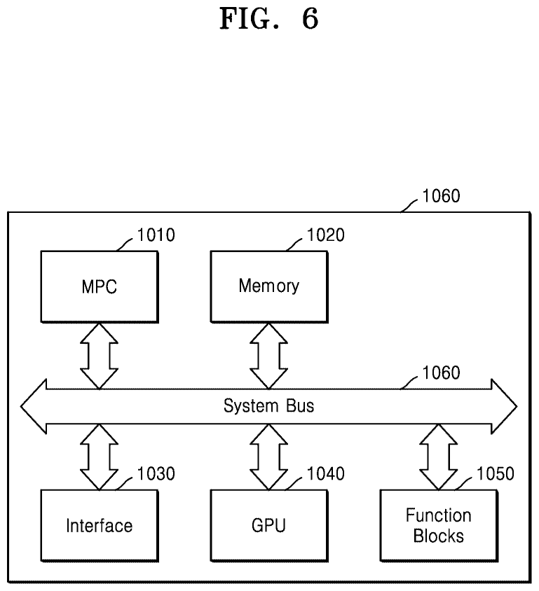

FIG. 6 is a schematic block diagram of a semiconductor package 1000 according to some example embodiments.

Referring to FIG. 6, the semiconductor package 1000 may include, for example, a micro-processor unit (MPC) 1010, a memory 1020, an interface 1030, a graphic-processor unit (GPU) 1040, functional blocks 1050, and/or a system bus 1060 connecting the above components. The semiconductor package 1000 may include, for example, both the micro-processor unit 1010 and the GPU 1040, or may include only one of the micro-processor unit 1010 and the graphic processor unit 1040.

The micro-processor unit 1010 may include, for example, a core and/or a cache. For example, the micro-processor unit 1010 may include a multi-core. Cores in the multi-core may have the same or different performance(s). Also, for example, the cores in the multi-core may be simultaneously activated or may be activated at different points in time.

The memory 1020 may store processing results in the functional blocks 1050, etc., according to the control from the micro-processor unit 1010. The interface 1030 may exchange information or signals with external devices. The graphic processor unit 1040 may perform graphic functions. For example, the GPU 1040 may execute a video codec and/or may process three-dimensional (3D) graphics. The functional blocks 1050 may perform, for example, various functions. For example, when the semiconductor package 1000 is or includes an application processor used in a mobile device, some of the functional blocks 1050 may perform, for example, one or more communication functions.

The semiconductor package 1000 may include any one of the semiconductor packages 1 and 1A described above with reference to FIGS. 1 to 4.

While inventive concepts have been particularly shown and described with reference to example embodiments thereof, it will be understood by one of ordinary skill in that art that various changes in form and details may be made therein without departing from the spirit and scope of inventive concepts as in the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

What is claimed is:

1. A semiconductor package comprising:
a lower redistribution structure including redistribution patterns;
a first semiconductor device on the lower redistribution structure;
a core layer on the lower distribution structure, the core layer laterally apart from the first semiconductor device and including a core insulating layer and core wires;
an encapsulation material on the lower redistribution structure, the encapsulation material at least partially covering
a side surface of the core layer,
an upper surface of the core layer,
a side surface of the first semiconductor device, and
an upper surface of the first semiconductor device;
a second semiconductor device on the encapsulation material; and
a heat dissipation structure laterally apart from the second semiconductor device and above the first semiconductor device,
wherein the core wires include core patterns and core vias,
upper vias at least partially extend through the encapsulation material and upper pads are on uppermost of the core patterns, the uppermost core patterns being on an uppermost surface of the core layer, the upper pads being integrally connected to the upper vias,
the upper vias connect the uppermost core patterns to the upper pads,
the upper pads are on the upper surface of the encapsulation material, and
upper surfaces and side surfaces of the upper pads are at least partially covered by a cover conductive layer and the cover conductive layer contacts the upper surface of the encapsulation material.

2. The semiconductor package of claim 1, wherein the upper pads are located vertically above the uppermost core patterns, the upper vias are vertically between the uppermost core patterns and the upper pads, and the uppermost core patterns, the upper vias, and the upper pads are aligned in a vertical direction.

3. The semiconductor package of claim 2, further comprising:
seed layers
between the encapsulation material and the upper pads,
between the upper vias and the encapsulation material, and
between the upper vias and the uppermost core patterns.

4. The semiconductor package of claim 3, further comprising:
an upper underfill layer between the second semiconductor device and the encapsulation material,
wherein the upper underfill layer contacts at least a part of the cover conductive layer and does not contact the upper pad.

5. The semiconductor package of claim 4, wherein an upper surface of the second semiconductor device and an upper surface of the heat dissipation structure are at same vertical levels as each other.

6. The semiconductor package of claim 4, wherein
the redistribution patterns include redistribution line patterns and redistribution vias,
the redistribution vias each have a horizontal width that increases when moving vertically away from the first semiconductor device, and
the core vias each have a horizontal width that increases when moving vertically away from the lower redistribution structure.

7. The semiconductor package of claim 6, wherein
the upper surface of the encapsulation material includes a first encapsulation material upper surface and a second encapsulation material upper surface, the first encapsulation material upper surface and the second encapsulation material upper surface being at different vertical levels, and
the vertical level of the first encapsulation material upper surface is higher than the vertical level of the second encapsulation material upper surface, and the vertical level of the second encapsulation material upper surface and the vertical level of the upper surface of the first semiconductor device are equal to each other.

8. The semiconductor package of claim 6, wherein
the first semiconductor device includes at least one of a central processor device chip, a graphic processing device chip, or an application processor chip, and
the second semiconductor device includes at least one memory chip.

9. The semiconductor package of claim 6, wherein a lower surface of the first semiconductor device contacts the upper surface of the lower redistribution structure.

10. The semiconductor package of claim 1, wherein a planar shape of the first semiconductor device does not overlap a planar shape of the second semiconductor device, and a planar shape of the heat dissipation structure includes the planar shape of the first semiconductor device.

11. The semiconductor package of claim 1, wherein
the heat dissipation structure includes silicon or a metal including at least one of aluminum (Al), copper (Cu), titanium (Ti), nickel (Ni), iron (Fe), cobalt (Co), palladium (Pd), platinum (Pt), aurum (Au), lead (Pb), Argentum (Ag), Carbon (C), tin (Sn), tungsten (W), and chromium (Cr), or any alloy thereof, and
the cover conductive layer includes at least one of Au or Ni, and the encapsulation material includes an epoxy mold compound (EMC).

12. The semiconductor package of claim 1, further comprising:
a thermal transfer film on the lower surface of the heat dissipation structure,
wherein a planar shape of the thermal transfer film is equal to or greater than a planar shape of the heat dissipation structure, and
the thermal transfer film includes a thermal interface material (TIM), the TIM including at least one of mineral oil, grease, gap filler putty, phase change gel, phase change material pads, or particle filled epoxy.

13. A semiconductor package comprising:
a lower redistribution structure including redistribution patterns;
a first semiconductor device on the lower redistribution structure;
a core layer laterally apart from the first semiconductor device, on the lower redistribution structure, and including a plurality of core insulating layers and core wires;
an encapsulation material on the lower redistribution structure and between the core layer and the first semiconductor device, the encapsulation material at least partially covering
a side surface of the core layer,
an upper surface of the core layer,
a side surface of the first semiconductor device, and
an upper surface of the first semiconductor device;
a second semiconductor device on the encapsulation material; and
a heat dissipation structure laterally apart from the second semiconductor device and above the first semiconductor device,
wherein the core wires include core patterns and core vias,
upper vias at least partially extend through the encapsulation material and upper pads are on uppermost of the core patterns, the uppermost core patterns being on an uppermost surface of the core layer, the upper pads being connected to the upper vias,
the upper vias connect the uppermost core patterns to the upper pads,
the upper pads are on the upper surface of the encapsulation material,
upper surfaces and side surfaces of the upper pads are at least partially covered by a cover conductive layer, the cover conductive layer contacting the upper surface of the encapsulation material,
a planar shape of the first semiconductor device does not overlap a planar shape of the second semiconductor device, and a planar shape of the heat dissipation structure includes the planar shape of the first semiconductor device,
the first semiconductor device includes at least one of a central processor device chip, a graphic processing device chip, or an application processor chip, and
the second semiconductor device includes at least one memory chip.

14. The semiconductor package of claim 13, further comprising:
seed layers extending
between the encapsulation material and the upper pads,
between the upper vias and the encapsulation material, and
between the upper vias and the uppermost core patterns; and
an upper underfill layer between the second semiconductor device and the encapsulation material,
wherein the upper underfill layer contacts at least a part of the cover conductive layer and does not contact the upper pad.

15. The semiconductor package of claim 14, wherein
the upper pads are located vertically above the uppermost core pattern, the upper vias are vertically between the uppermost core patterns and the upper pads, and the uppermost core patterns, the upper vias, and the upper pads are aligned in a vertical direction.

16. The semiconductor package of claim 15, wherein
the redistribution patterns include redistribution line patterns and redistribution vias,
the redistribution vias each have a horizontal width that increases when moving vertically away from the first semiconductor device, and
the core vias each have a horizontal width that increases when moving vertically away from the lower redistribution structure.

17. The semiconductor package of claim 16, wherein
the upper surface of the encapsulation material includes a first encapsulation material upper surface and a second encapsulation material upper surface, the first encapsulation material upper surface and the second encapsulation material upper surface being at different vertical levels from each other, and
the vertical level of the first encapsulation material upper surface is higher than the vertical level of the second encapsulation material upper surface, and the vertical level of the second encapsulation material upper surface and the vertical level of the upper surface of the first semiconductor device are equal to each other.

18. The semiconductor package of claim 17, further comprising:
a thermal transfer film is on the lower surface of the heat dissipation structure,
wherein a planar shape of the thermal transfer film is same as or greater than a planar shape of the heat dissipation structure, and
the thermal transfer film includes a thermal interface material (TIM), the TIM including at least one of mineral oil, grease, gap filler putty, phase change gel, phase change material pads, or particle filled epoxy.

19. The semiconductor package of claim 18, wherein
a thickness of the encapsulation material in the vertical direction is 200 μm to 500 μm, and
a vertical distance between an upper surface of an uppermost portion of the core insulating material at an uppermost portion and the upper surface of the encapsulation material is 50 μm to 90 μm.

20. A semiconductor package, comprising:
a lower redistribution structure including redistribution patterns;
a first semiconductor device on the lower redistribution structure;
a core layer laterally apart from the first semiconductor device, on the lower redistribution structure, and including core wires and a core insulating layer, the core wires including core patterns and core vias;
an encapsulation material on the lower redistribution structure and at least partially covering
a side surface of the core layer,
an upper surface of the core layer,
a side surface of the first semiconductor device, and
an upper surface of the first semiconductor device;
a second semiconductor device on the encapsulation material;
a heat dissipation structure laterally apart from the second semiconductor device and above the first semiconductor device;
an upper underfill layer between the second semiconductor device and the encapsulation material; and
a thermal transfer film on the lower surface of the heat dissipation structure,
wherein upper vias at least partially extending through the encapsulation material and upper pads integrally extending from the upper vias are on uppermost of the core patterns, the uppermost core patterns on an uppermost surface of the core layer,
the upper vias connect the uppermost core patterns to the upper pads,
the upper pads are on the upper surface of the encapsulation material,
upper surfaces and side surfaces of the upper pads are at least partially covered by a cover conductive layer, the cover conductive layer contacting the upper surface of the encapsulation material,
the upper pads are located vertically above the uppermost core pattern, the upper vias are vertically between the uppermost core patterns and the upper pads, and the uppermost core patterns, the upper vias, and the upper pads are aligned in a vertical direction,
seed layers extend
between the encapsulation material and the upper pads,
between the upper vias and the encapsulation material, and
between the upper vias and the uppermost core patterns,
the upper underfill layer contacts with at least a part of the cover conductive layer and does not contact the upper pad,
the upper surface of the second semiconductor device and an upper surface of the heat dissipation structure are at same vertical levels as each other,
the redistribution patterns include redistribution line patterns and redistribution vias,
the redistribution vias each have a horizontal width that increases when moving vertically away from the first semiconductor device and the core vias each have a horizontal width that increases when moving vertically away from the lower redistribution structure,
the first semiconductor device includes at least one of a central processor device chip, a graphic processing device chip, and an application processor chip, and the second semiconductor device includes at least one memory chip,
a lower surface of the first semiconductor device contacts the upper surface of the lower redistribution structure,
a planar shape of the first semiconductor device does not overlap a planar shape of the second semiconductor device, a planar shape of the heat dissipation structure includes the planar shape of the first semiconductor device, and a planar shape of the thermal transfer film is same as or greater than a planar shape of the heat dissipation structure,
the heat dissipation structure includes at least one of silicon or a metal including at least one of aluminum (Al), copper (Cu), titanium (Ti), nickel (Ni), iron (Fe), cobalt (Co), palladium (Pd), platinum (Pt), aurum (Au), lead (Pb), Argentum (Ag), Carbon (C), tin (Sn), tungsten (W), and chromium (Cr), or any alloy thereof,
the cover conductive layer includes at least one of Au or Ni, and the encapsulation material includes an epoxy mold compound (EMC),
the thermal transfer film includes a thermal interface material (TIM), the TIM including at least one of mineral oil, grease, gap filler putty, phase change gel, phase change material pads, or particle filled epoxy, and
a thickness of the encapsulation material in the vertical direction is 200 μm to 500 μm, and a distance in the vertical direction between an upper surface of an uppermost portion of the core insulating layer and the upper surface of the encapsulation material is 50 μm to 90 μm.
